(19) United States
(12) Patent Application Publication
(10) Pub. No.: US 2007/0211440 A1
(43) Pub. Date: Sep. 13, 2007

(54) MP3 player seat unit

(76) Inventor: Po-Hsiung Yu, Taoyuan (TW)

Correspondence Address: SCHMEISER, OLSEN & WATTS, 22 CENTURY HILL DRIVE, SUITE 302, LATHAM, NY, 12110, US

(21) Appl. No.: 11/371,110

(22) Filed: Mar. 8, 2006

(51) Int. Cl. H05K 5/00

(52) U.S. Cl. 361/752

(57) ABSTRACT

An MP3 player seat unit includes a player seat having a receiving slot provided at a front center for receiving an MP3 player therein, a sound source terminal in the receiving slot for plugging into a sound source jack on the MP3 player to output music signals, an amplifier and a loudspeaker built in two sides of the receiving slot, a receiving space formed at a rear lower central area of the player seat, and two battery compartments formed at two sides of the receiving space for supplying power to internal circuits of the player seat; a signal cable having a first terminal connector located in the receiving space for connecting to a female connector on the MP3 player, and a second terminal connector for connecting to an external computer or other music signal source apparatus; and a back cover for covering the receiving space and the two battery compartments.

### FIELD OF THE INVENTION

The present invention relates to an MP3 player seat, and more particularly to an MP3 player seat associated with a signal cable to provide the functions of downloading music and charging the player seat.

### BACKGROUND OF THE INVENTION

An MPEG Layer 3, which is briefly referred to as MP3, is a type of music file compression software for highly compressing music files to reduce the memory space for storing the music files. An MP3 player is a device that directly employs the MP3 compression software to play music files, it has the advantages of being light and compact and convenient for use, and has been widely accepted by music lovers.

A conventional MP3 player is provided at a bottom with a female connector and a sound source jack. A simple signal cable or a signal transmitting device may be plugged in the female connector on the MP3 player to connect the MP3 player to an external computer or other apparatus, so as to download music signals and charge the MP3 player. The sound source jack may receive a sound source terminal, so as to connect the MP3 player to an external sound-playing apparatus.

An earphone is one of the common external sound-playing apparatus, and has small volume to be conveniently portable for using outdoors or in a moving condition to play music for personal purpose. However, to use the earphone indoors or in a fixed or not frequently changed place would adversely hinder a user's work.

Therefore, there is an MP3 player seat particularly developed for using the MP3 player indoors or in a fixed place conveniently. The conventional MP3 player seat mainly includes a seat provided with a socket for receiving an MP3 player therein. The socket is internally provided with a sound source terminal corresponding to the sound source jack on the MP3 player.

The sound source terminal can also be connected to related amplifier and loudspeaker. When the MP3 player is inserted in the socket of the player seat, the sound source jack thereof is engaged with the sound source terminal on the player seat to enable direct playing of music signals from the MP3 player seat.

The above-mentioned MP3 player seat is designed to play music only. There is not any element provided in the socket of the player seat for connecting with the female connector at the bottom of the MP3 player. That is, when the MP3 player is inserted in the player seat for playing music, it is not able to connect to a computer via a signal cable. When it is desired to charge the MP3 player or use the MP3 player to down load music signals, a user has to remove the MP3 player from the player seat first. This is of course inconvenient for the user to do so.

It is therefore tried by the inventor to develop an MP3 player seat unit to eliminate the drawbacks existed in the conventional MP3 player seat.

### SUMMARY OF THE INVENTION

A primary object of the present invention is to provide an MP3 player seat unit that not only has a player seat with a loudspeaker for playing music from an MP3 player on the player seat, but also has a signal cable associated with the player seat for connecting the MP3 player on the player seat to an external sound source, making the MP3 player more convenient for use.

To achieve the above and other objects, the MP3 player seat unit according to the present invention includes a player seat having a receiving slot provided at a front central area thereof for receiving an MP3 player therein, a sound source terminal projected from an inner bottom of the receiving slot for plugging into a sound source jack correspondingly provided on the MP3 player to output music signals, an amplifier and a loudspeaker internally built at two sides of the receiving slot, a receiving space formed at a rear lower centralS area of the player seat, and two battery compartments formed at two sides of the receiving space for supplying power to internal circuits of the player seat; a signal cable having a first terminal connector located in the receiving space of the player seat for connecting to a female connector of the MP3 player, and a second terminal connector for connecting to an external computer or other music signal source apparatus; and a back cover closed to a rear lower side of the player seat for covering the receiving space and the two battery compartments.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of an MP3 player seat unit according to the present invention;

FIG. 2 is a partially assembled view of FIG. 1;

FIG. 3 is a fully assembled view of FIG. 1;

FIG. 4 is a rear perspective view showing the use of the MP3 player seat unit of the present invention;

FIG. 5 is a front perspective view showing the use of the MP3 player seat unit of the present invention; and

FIG. 6 is an assembled sectional view of the MP3 player seat unit of the present invention with an MP3 player held thereon.

### DETAILED DESCRIPTION OF THE PREFERRED EMBODIMENTS

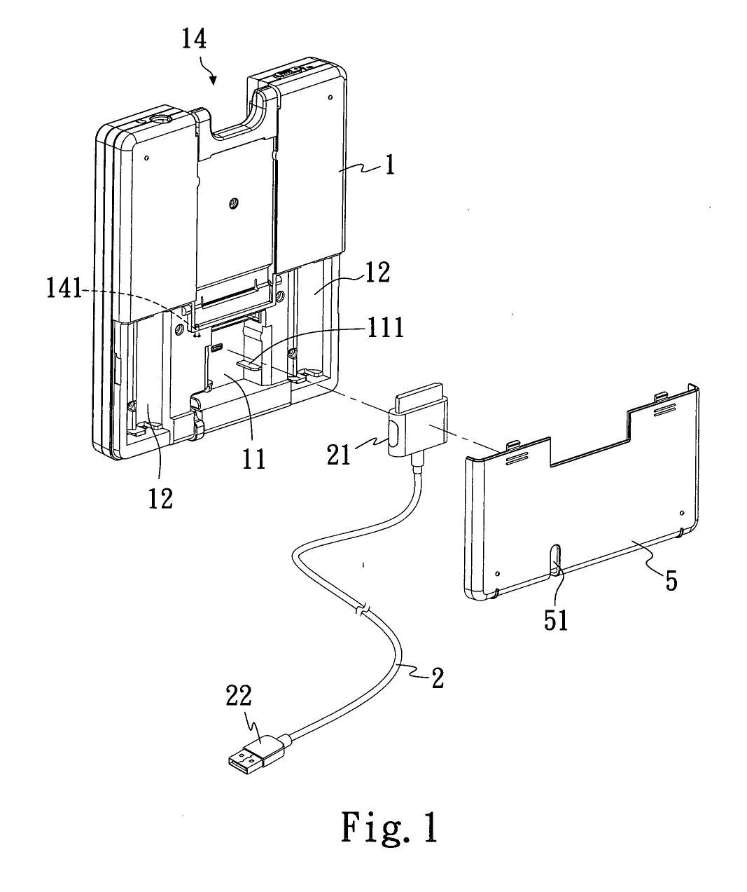

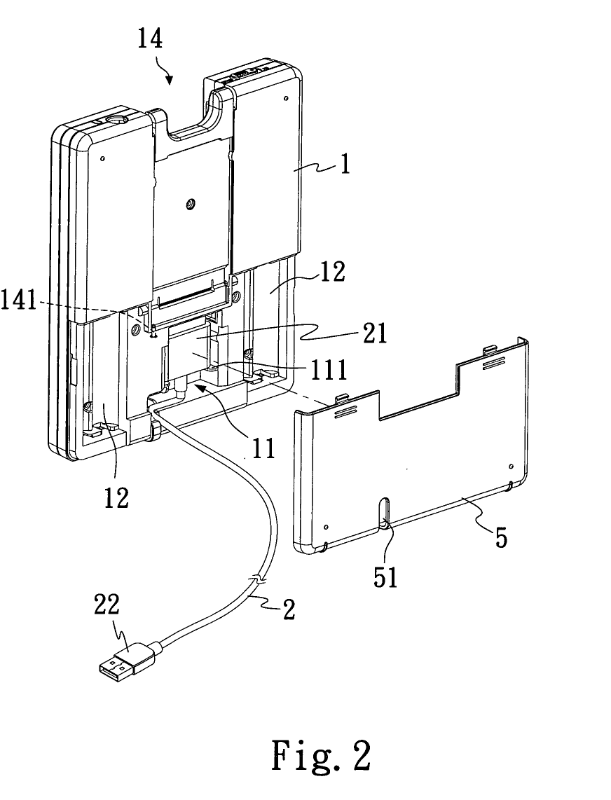

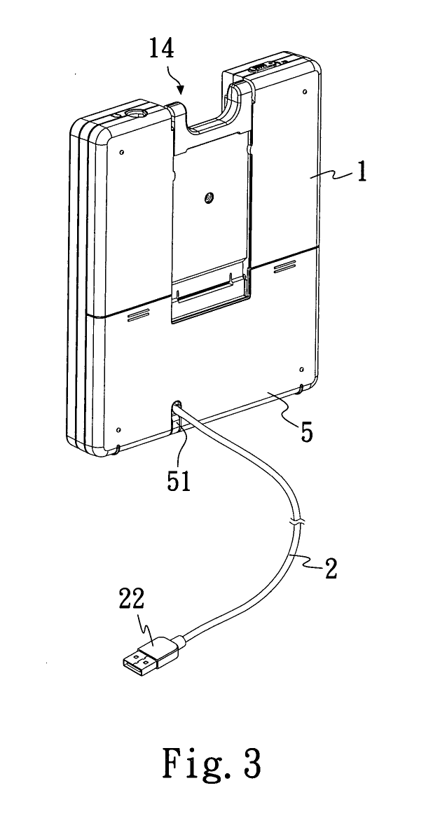

Please refer to FIG. 1 that is an exploded perspective view of an MP3 player seat unit according to the present invention, and to FIGS. 2 and 3 that are partially and fully assembled perspective views, respectively, of FIG. 1. As shown, the MP3 player seat unit includes a player seat 1, a signal cable 2, and a back cover 5.

The player seat 1 is provided at a front central area with a receiving slot 14 for receiving an MP3 player therein. A sound source terminal 141 is projected from an inner bottom of the receiving slot 14. An amplifier and a loudspeaker may be internally built at two sides of the receiving slot 14. A receiving space 11 is formed at a rear lower central area of the player seat 1, and is provided near middle sections of two lateral walls with an inward projected stop plate 111 each. Two battery compartments 12 are separately formed at two sides of the receiving space 11 for accommodating batteries therein.

The signal cable 2 is provided at an end with a first terminal connector 21, which is upwardly located in the receiving space 11 of the player seat 1 and stably supported on the two stop plates 111, and at the other end with a second terminal connector 22 for connecting to an external computer or other music signal source apparatus.

The back cover 5 is removably closed to a rear lower area of the player seat 1 to cover the receiving space 11 and the two battery compartments 12. A notch 51 is provided to one side of a lower edge of the back cover 5 for the signal cable 2 to extend to an outer side of the player seat 1 via the notch 51.

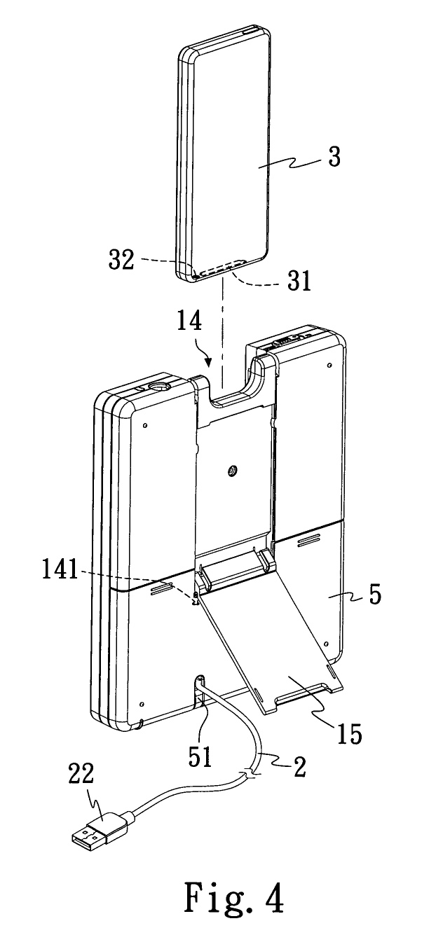

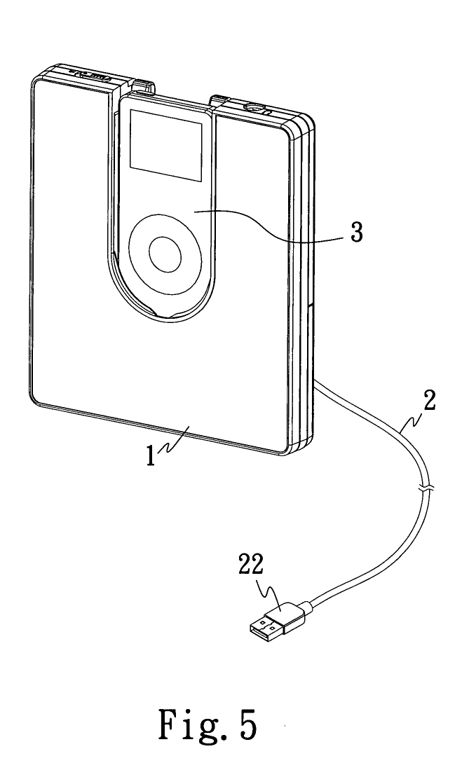

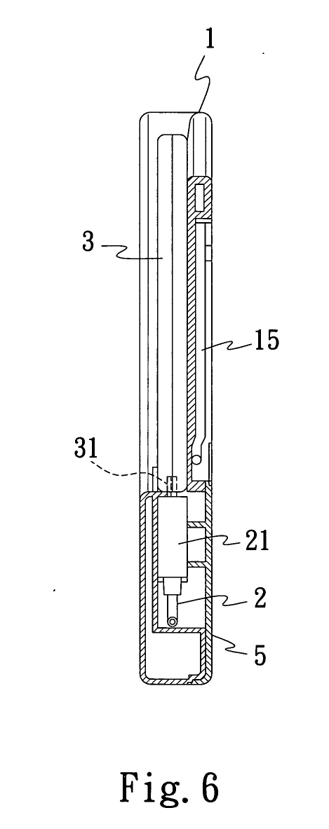

FIGS. 4 and 5 are rear and front perspective views, respectively, showing the use of the MP3 player seat unit of the present invention; and FIG. 6 is an assembled sectional view of FIG. 5. Please refer to FIGS. 4, 5, and 6 at the same time. The player seat 1 is further provided at a rear upper middle area with a back support 15, which can be pivotally turned from the rear side of the player seat 1 to a rearward downward inclined position, so as to properly support the player seat 1 for the same to stably stand in a slightly rearward inclined position. When a MP3 player 3 is inserted into the receiving slot 14 on the player seat 1, a female connector 31 provided at a bottom of the MP3 player 3 is directly connected with the first terminal connector 21 of the signal cable 2, and the sound source terminal 141 at the bottom of the receiving slot 14 is directly plugged into a sound source jack 32 also provided at the bottom of the MP3 player 3. Thus, the MP3 player 3 on the player seat 1 could be directly connected to an external computer or other music signal source apparatus via the signal cable 2 for downloading music signals or charging the MP3 player 3. Meanwhile, the MP3 player 3 may output music signals via the sound source terminal 141 to the built-in amplifier and loudspeaker on the player seat 1 for playing music.

Batteries in the battery compartments 12 provide power required by all internal circuits of the player seat 1.

With the above arrangements, the MP3 player seat unit of the present invention also includes the signal cable to provide the functions of downloading music, charging the MP3 player, and playing music, and is therefore novel and practical for use.

What is claimed is:

1. An MP3 player seat unit, comprising:
a player seat having a receiving slot provided at a front central area thereof for receiving an MP3 player therein, a sound source terminal projected from an inner bottom of said receiving slot for plugging into a sound source jack correspondingly provided on the MP3 player in said receiving slot so as to output music signals, an amplifier and a loudspeaker internally built at two sides of said receiving slot, a receiving space formed at a rear lower central area of said player seat, and two battery compartments separately formed at two sides of said receiving space for accommodating batteries therein to supply power needed by internal circuits of said player seat;
a signal cable being provided at an end with a first terminal connector, which is located in said receiving space of said player seat for connecting to a female connector provided at a bottom of the MP3 player in said receiving slot, and at the other end with a second terminal connector for connecting to an external computer or other music signal source apparatus; and
a back cover being removably closed to a rear lower area of said player seat to cover said receiving space and said two battery compartments.

2. The MP3 player seat unit as claimed in claim 1, wherein said player seat is further provided at a rear upper middle area with a back support, which can be pivotally turned from the rear side of said player seat to support said player seat in a slightly rearward inclined position.

3. The MP3 player seat unit as claimed in claim 1, wherein said receiving space on said player seat is provided near a middle section of two lateral walls with a stop plate each, on which said first terminal connector of said signal cable in said receiving space of said player seat is stably supported.
